(19) United States
(12) Patent Application Publication
(10) Pub. No.: US 2025/0164615 A1
(43) Pub. Date: May 22, 2025

(54) DISTANCE MEASURING DEVICE

(71) Applicant: SONY SEMICONDUCTOR SOLUTIONS CORPORATION, KANAGAWA (JP)

(72) Inventors: HIROYUKI HIRANO, KANAGAWA (JP); AKIHIKO MIYANOHARA, KANAGAWA (JP); NAOTO NAGAKI, KANAGAWA (JP); NORIAKI ENDO, KANAGAWA (JP)

(21) Appl. No.: 18/727,612

(22) PCT Filed: Jan. 12, 2023
(86) PCT No.: PCT/JP2023/000685

§ 371 Date: Jul. 9, 2024

(30) Foreign Application Priority Data
Jan. 20, 2022 (JP) 2022-007311

(51) Int. Cl. G01S 7/4865; G01S 7/484; G01S 7/4863; G01S 17/10

(52) U.S. Cl. CPC G01S 7/4865; G01S 7/484; G01S 7/4863; G01S 17/10

(57) ABSTRACT

To make it possible to accurately measure a distance without depending on fluctuation in a power supply voltage. A distance measuring device includes: an oscillator that generates a first clock signal whose oscillation frequency changes according to the fluctuation in the power supply voltage; a first counting unit that repeats operation of counting the number of the first clock signals in a first period set in advance a plurality of times; a jitter detection unit that performs averaging processing of count values for the plurality of times by the first counting unit to detect jitter due to the fluctuation in the power supply voltage; a light receiving element that emits a light signal to an object and receives a reflected light signal from the object every second period including a plurality of the first periods; a first histogram generation unit that generates a first histogram representing an appearance frequency for each of timings at which the reflected light signal is received; and a distance calculation unit that measures a distance to the object on the basis of the first histogram.

### TECHNICAL FIELD

The present disclosure relates to a distance measuring device.

### BACKGROUND ART

There is known a distance measuring device of a direct time of flight (dToF) method that emits a light signal to an object, receives a reflected light signal from the object, and measures a distance to the object from a time difference between a light emission timing of the light signal and a light reception timing of the reflected light signal.

Since an ambient light signal such as sunlight is also received by a light receiving element that receives the reflected light signal by this type of distance measuring device, it is common to repeatedly perform light emission of the light signal and light reception of the reflected light signal, generate a histogram representing the light reception timing and light reception frequency of the reflected light signal, and determine the light reception timing by a peak position of the histogram.

However, in the dToF, since a plurality of light receiving elements simultaneously receives the reflected light signal, a power supply voltage may temporarily decrease at a moment of receiving the reflected light signal. When the power supply voltage of an oscillator that controls the light emission timing of the plurality of light emitting elements fluctuates, the light emission timing of the light signal fluctuates, and variation occurs in a frequency distribution of the histogram.

Fluctuation in an oscillation frequency of the oscillator due to fluctuation in the power supply voltage is referred to as jitter. Patent Document 1 discloses a technology of measuring jitter of an output of an oscillator and detecting a substrate current caused by on/off of a digital circuit.

### CITATION LIST

### Patent Document

Patent Document 1: Japanese Patent Application Laid-Open No. 2003-142586

### SUMMARY OF THE INVENTION

### Problems to be Solved by the Invention

However, Patent Document 1 does not disclose a specific method for measuring jitter. In addition, Patent Document 1 relates to a technology unrelated to a distance measuring device, and does not consider suppressing variation in frequency distribution of a histogram by measured jitter. Further, in Patent Document 1, a jitter measurement device is provided separately from a semiconductor integrated circuit, and a specific configuration for measuring jitter in the semiconductor integrated circuit is neither disclosed nor suggested in Patent Document 1.

Thus, the present disclosure provides a distance measuring device capable of accurately measuring a distance without depending on fluctuation in a power supply voltage.

### Solutions to Problems

In order to solve the problem described above, according to the present disclosure, there is provided a distance measuring device including:
an oscillator that generates a first clock signal whose oscillation frequency changes according to fluctuation in a power supply voltage;
a first counting unit that repeats operation of counting the number of the first clock signals in a first period set in advance a plurality of times;
a jitter detection unit that performs averaging processing of count values for the plurality of times by the first counting unit to detect jitter due to the fluctuation in the power supply voltage;
a light receiving element that emits a light signal to an object and receives a reflected light signal from the object every second period including a plurality of the first periods;
a light reception information detection unit that detects timing information at which the reflected light signal is received; and
a distance calculation unit that measures a distance to the object on the basis of the timing information detected by the light reception information detection unit.

The light reception information detection unit may generate a first histogram representing an appearance frequency for each of timings at which the reflected light signal is received.

The first period may be a fixed period.

The jitter detection unit may calculate a difference between a count value by the first counting unit acquired at a timing of a start of the first period and a count value by the first counting unit acquired at a timing of an end of the first period a plurality of times, and average a plurality of the differences.

A second counting unit may be further included that repeats operation of counting the number of the first clock signals in the second period a plurality of times, and
the jitter detection unit may calculate an average value of count values by the second counting unit counted for each of the second periods and an average value of count values by the first counting unit counted for each of the individual first periods in the second period, and detect the jitter on the basis of a reciprocal of the average value of the count values by the second counting unit counted for each of the second periods and a reciprocal of the average value of the count values by the first counting unit counted for each of the individual first periods in the second period.

A histogram correction unit may be further included that corrects the first histogram on the basis of the jitter detected by the jitter detection unit to generate a corrected histogram, and
the distance calculation unit may measure the distance to the object on the basis of the corrected histogram.

The histogram correction unit may correct the first histogram such that an appearance frequency for each of timings of an ambient light signal received by the light receiving element is constant to generate the corrected histogram.

There may be further provided:
a first time digital converter that generates a first digital signal according to the reflected light signal received by the light receiving element;
a pseudo input generation unit that generates a pseudo input signal according to an ambient light signal not including the reflected light signal;
a second time digital converter that converts the pseudo input signal into a second digital signal; and
a second histogram generation unit that generates a second histogram representing an appearance frequency for each of timings at which the ambient light signal is received,
the light reception information detection unit may generate the first histogram on the basis of the first digital signal, and
the histogram correction unit may correct the first histogram on the basis of the jitter detected by the jitter detection unit and the second histogram to generate the corrected histogram.

The light reception information detection unit may generate the first histogram corresponding to a signal including the reflected light signal and the ambient light signal, a signal including only the ambient light signal, or the reflected light signal not including the ambient light signal.

The light reception information detection unit may generate the first histogram in a pseudo manner on the basis of the signal including only the ambient light signal.

A jitter correction unit may be further included that corrects a frequency characteristic of the jitter detected by the jitter detection unit, and
the histogram correction unit may correct the first histogram on the basis of the jitter corrected by the jitter correction unit to generate the corrected histogram.

The jitter correction unit may correct at least one of an amplitude or a phase of the jitter detected by the jitter detection unit.

The jitter correction unit may correct at least one of an amplitude or a phase of the jitter detected by the jitter detection unit, on the basis of temperature information and the jitter detected by the jitter detection unit.

A jitter addition unit may be further included that controls timings of at least some signals from when the light receiving element receives the reflected light signal to when the light reception information detection unit generates the first histogram on the basis of the jitter detected by the jitter detection unit.

There may be further provided:
a clock generation unit that generates a second clock signal having an oscillation frequency not depending on the fluctuation in the power supply voltage, on the basis of a reference clock signal;
a counting window generation unit that generates the first period in synchronization with the second clock signal; and
a light emission timing control unit that controls a light emission timing of a light emitting element that emits the light signal in synchronization with the second clock signal.

The jitter addition unit may add the jitter to the second clock signal, and
the light emission timing control unit may control the light emission timing of the light emitting element that emits the light signal in synchronization with the second clock signal to which the jitter is added.

The jitter addition unit may control at least one of an oscillation frequency or a phase of the second clock signal on the basis of the jitter detected by the jitter detection unit.

There may be further provided:
a clock generation unit that generates a second clock signal having an oscillation frequency not depending on the fluctuation in the power supply voltage, on the basis of a reference clock signal;
a first time digital converter that generates a first digital signal according to the reflected light signal;
a first control unit that controls the first time digital converter and the light reception information detection unit;
a second control unit that controls the first control unit in synchronization with the second clock signal; and
a pixel array unit including a plurality of the light receiving elements, and
the jitter addition unit may add the jitter to at least one of a plurality of electric signals according to a plurality of the reflected light signals output from the plurality of the light receiving elements in the pixel array unit, a first control signal for controlling the first control unit, or a second control signal that is output from the second control unit and is for controlling the first control unit.

According to the present disclosure, there is provided a distance measuring device including:
a light receiving element that emits a light signal to an object and receives a reflected light signal from the object every second period including a plurality of first periods;
a first time digital converter that generates a first digital signal according to the reflected light signal;
a first histogram generation unit that generates a first histogram representing an appearance frequency for each of timings at which the reflected light signal is received;
a pseudo input generation unit that generates a pseudo input signal according to an ambient light signal not including the reflected light signal;
a second time digital converter that converts the pseudo input signal into a second digital signal;
a second histogram generation unit that generates a second histogram representing an appearance frequency for each of timings at which the ambient light signal is received;
a histogram correction unit that corrects the first histogram on the basis of the second histogram to generate a corrected histogram; and
a distance calculation unit that measures a distance to the object on the basis of the corrected histogram.

A pixel array unit including a plurality of the light receiving elements may be further included, and
a plurality of the pseudo input generation units and a plurality of the second time digital converters may be provided in association with two or more of the light receiving elements arranged separately in the pixel array unit.

### BRIEF DESCRIPTION OF DRAWINGS

FIG. 1 is a block diagram illustrating a configuration of a main part of a detection unit that detects jitter.

FIG. 2 is a diagram illustrating operation of a circulation counter, a first latch circuit, a second latch circuit, and a synchronization processing unit of FIG. 1.

FIG. 3 is a block diagram illustrating a schematic configuration of a distance measuring device according to a first embodiment.

FIG. 4 is a block diagram of a distance measuring system in which the configuration of FIG. 3 is further embodied.

FIG. 5 is a flowchart illustrating processing operation of the distance measuring device according to the first embodiment.

FIG. 6A is a diagram illustrating an example of a light emission period of a light emitting element in a light source unit, fluctuation in a power supply voltage, and a count value counted by a counting unit.

FIG. 6B is a diagram illustrating an example of a processing result in step S2 of FIG. 5.

FIG. 6C is a diagram illustrating an example of a processing result in step S3 of FIG. 5.

FIG. 6D is a diagram illustrating an example of a result of detection processing in step S4 of FIG. 5.

FIG. 7A is a diagram illustrating an example of interpolation processing.

FIG. 7B is a diagram illustrating an example of jitter correction processing.

FIG. 7C is a diagram schematically illustrating processing of correcting a first histogram.

FIG. 8 is a block diagram illustrating a schematic configuration of a distance measuring device according to a second embodiment.

FIG. 9 is a block diagram of a distance measuring system in which the configuration of FIG. 8 is further embodied.

FIG. 10A is a diagram illustrating a first example of a specific configuration of a jitter addition unit.

FIG. 10B is a diagram illustrating a second example of the specific configuration of the jitter addition unit.

FIG. 11 is a block diagram illustrating a schematic configuration of a distance measuring device according to a third embodiment.

FIG. 12 is a block diagram of a distance measuring system in which the configuration of FIG. 11 is further embodied.

FIG. 13 is a diagram illustrating an example of generating a histogram including reflected light and ambient light.

FIG. 14 is a diagram illustrating an example of generating a histogram including only reflected light.

FIG. 15 is a block diagram illustrating an internal configuration of a distance measuring system according to a fourth embodiment.

FIG. 16 is a layout diagram illustrating an example in which a pseudo input generation unit, a second time digital converter, and a second histogram generation unit are arranged at four corners of a pixel array unit.

FIG. 17 is a block diagram illustrating an example of a schematic configuration of a vehicle control system.

FIG. 18 is an explanatory diagram illustrating an example of installation positions of an outside-vehicle information detecting section and an imaging section.

### MODE FOR CARRYING OUT THE INVENTION

Hereinafter, embodiments of a distance measuring device and an electronic device will be described with reference to the drawings. Hereinafter, while principal components of the distance measuring device and the electronic device will be mainly described, the distance measuring device and the electronic device can have components and functions that are not illustrated or described. The following description does not exclude components and functions that are not illustrated or described.

### First Embodiment

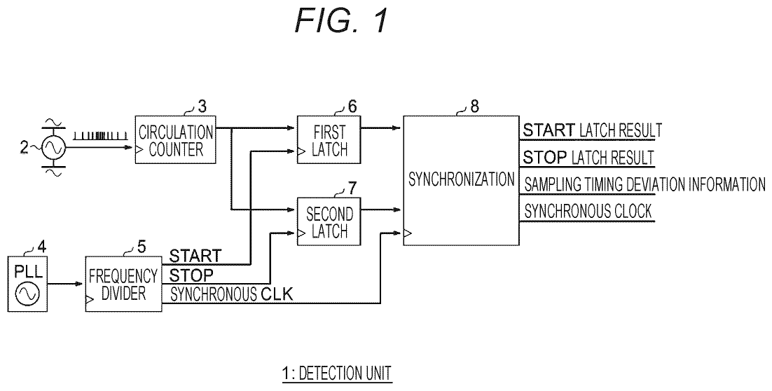

FIG. 1 is a block diagram illustrating a configuration of a main part of a detection unit 1 that detects jitter. The detection unit 1 of FIG. 1 includes an oscillator 2, a circulation counter 3, a PLL circuit 4, a frequency divider 5, a first latch circuit 6, a second latch circuit 7, and a synchronization processing unit 8.

The oscillator 2 generates a first clock signal whose oscillation frequency changes according to fluctuation in a power supply voltage. The oscillator 2 is an oscillator in which feedback control of an oscillation frequency is not performed with respect to the fluctuation in the power supply voltage, and is also referred to as a free-run oscillator. The oscillation frequency of the first clock signal changes sensitively to the fluctuation in the power supply voltage. In addition, the oscillator 2 may generate a first clock signal whose oscillation frequency changes according to not only the fluctuation in the power supply voltage but also fluctuation in an environment temperature or a manufacturing process.

The circulation counter 3 repeatedly performs counting operation in synchronization with the first clock signal generated by the oscillator 2. More specifically, the circulation counter 3 repeatedly performs the counting operation from a minimum count value to a maximum count value in synchronization with the first clock signal. When the oscillation frequency of the first clock signal changes according to the fluctuation in the power supply voltage, a count value by the circulation counter 3 also changes.

As described later, the circulation counter 3 functions as a first counting unit that repeats operation of counting the number of first clock signals in a first period set in advance a plurality of times, and also functions as a second counting unit that repeats operation of counting the number of first clock signals in a second period including a plurality of first periods a plurality of times. The first period is a time width of a counting window described later.

The PLL circuit 4 generates a second clock signal not depending on the power supply voltage by PLL control or appropriate power supply impedance separation in synchronization with a reference clock signal. That is, the PLL circuit 4 generates the second clock signal having a substantially fixed oscillation frequency even when the power supply voltage fluctuates.

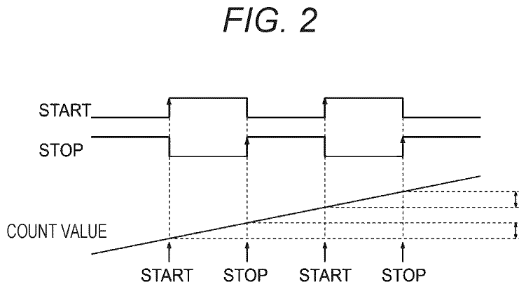

The frequency divider 5 divides the second clock signal to generate a START signal, a STOP signal, and a synchronous clock signal. FIG. 2 described later illustrates an example in which the START signal and the STOP signal have opposite phases, but the START signal and the STOP signal have any phase relationship. The synchronous clock signal is a signal synchronized with the START signal and the STOP signal. The frequency divider 5 can arbitrarily set a timing (hereinafter, a sampling timing) for dividing the second clock signal generated by the PLL circuit 4 from the outside. As a result, it is possible to arbitrarily shifts a timing at which the first latch circuit 6 and the second latch circuit 7 latch the count value by the circulation counter 3.

The first latch circuit 6 latches the count value by the circulation counter 3 at a rising edge of the START signal. The second latch circuit 7 latches the count value by the circulation counter 3 at a rising edge of the STOP signal.

The synchronization processing unit 8 outputs the count value latched by the first latch circuit 6, the count value latched by the second latch circuit 7, an amount of deviation of the sampling timing input to the frequency divider 5, and the synchronous clock signal in synchronization with the synchronous clock signal generated by the frequency divider 5.

Although not illustrated in FIG. 1, a block for detecting the jitter due to the fluctuation in the power supply voltage is provided at a subsequent stage of the synchronization processing unit 8.

FIG. 2 is a diagram illustrating operation of the circulation counter 3, the first latch circuit 6, the second latch circuit 7, and the synchronization processing unit 8 of FIG. 1. The first latch circuit 6 repeatedly latches the count value by the circulation counter 3 at the rising edge of the START signal, and the second latch circuit 7 repeatedly latches the count value by the circulation counter 3 at the rising edge of the STOP signal. The jitter can be detected by repeatedly detecting a difference between the count value by the first latch circuit 6 and the count value by the second latch circuit 7.

The detection unit 1 of FIG. 1 detects an amount of the fluctuation in the power supply voltage as a difference between the count values by the circulation counter 3. Since the circulation counter 3 repeats the counting operation, the difference between the count values can be repeatedly detected by outputs of the synchronization processing unit 8. The differences are averaged, whereby the jitter can be detected. The jitter refers to a deviation of timing of an edge of a certain electrical pulse from ideal timing.

The jitter detected by the detection unit 1 is a value depending on the amount of the fluctuation in the power supply voltage, and can be used, for example, for correction of a histogram in the distance measuring device.

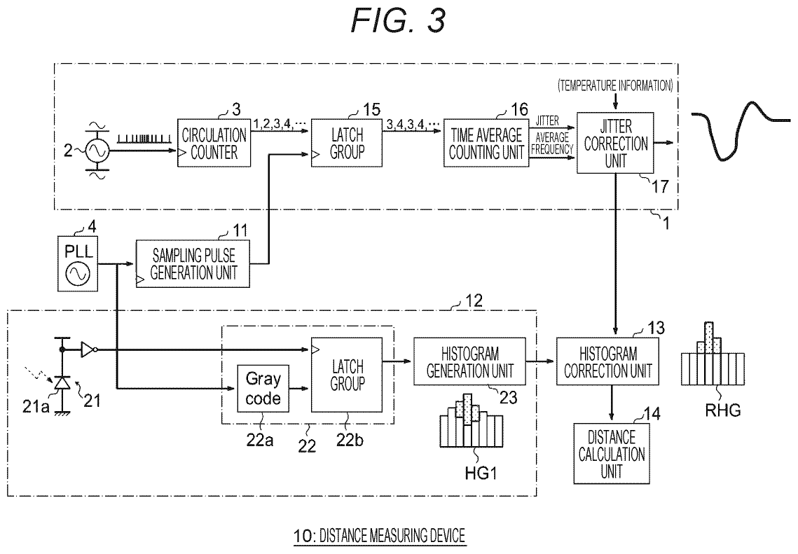

FIG. 3 is a block diagram illustrating a schematic configuration of a distance measuring device 10 according to a first embodiment. The distance measuring device 10 of FIG. 3 includes the detection unit 1, the PLL circuit 4, a sampling pulse generation unit 11, a distance measurement processing unit 12, a histogram correction unit 13, and a distance calculation unit 14.

The detection unit 1 of FIG. 3 detects the jitter on the basis of a result of repeatedly detecting the difference between the count values by processing operation similar to that of the detection unit 1 of FIG. 1. The detection unit 1 of FIG. 3 includes the oscillator 2, the circulation counter 3, a latch group 15, a time average counting unit 16, and a jitter correction unit 17.

Similarly to the oscillator 2 of FIG. 1, the oscillator 2 of FIG. 3 is a free-run oscillator in which the oscillation frequency changes according to the fluctuation in the power supply voltage. The circulation counter 3 of FIG. 3 is similar to the circulation counter 3 of FIG. 1, and repeatedly performs counting operation between the minimum count value and the maximum count value in synchronization with the first clock signal generated by the oscillator 2.

The latch group 15 of FIG. 3 performs latch operation similar to that of the first latch circuit 6 and the second latch circuit 7 of FIG. 1. The time average counting unit 16 of FIG. 3 performs averaging processing of repeatedly detecting and averaging a difference between the count value latched by the first latch circuit 6 and the count value latched by the second latch circuit 7 in the latch group 15, and detects the jitter due to the fluctuation in the power supply voltage. The time average counting unit 16 is also referred to as a jitter detection unit.

The time average counting unit 16 calculates a difference between the count value by the circulation counter 3 acquired at a timing of a start of the first period and the count value by the circulation counter 3 acquired at a timing of an end of the first period a plurality of times, and averages these differences.

The jitter correction unit 17 corrects a frequency characteristic of the jitter detected by the time average counting unit 16. A reason why the frequency characteristic need to be corrected is that there is a deviation between a frequency characteristic of the detection unit 1 and a frequency characteristic of the distance measurement processing unit 12, and in order to correct a histogram generated by the distance measurement processing unit 12 on the basis of the jitter generated by the detection unit 1, it is necessary to match the jitter generated by the detection unit 1 with the frequency characteristic of the distance measurement processing unit 12.

More specifically, the jitter correction unit 17 may correct at least one of an amplitude or a phase of the jitter output from the time average counting unit 16. In addition, the jitter correction unit 17 may correct the frequency characteristic of the jitter in consideration of temperature information measured by a temperature sensor or the like (not illustrated in FIG. 3).

The PLL circuit 4 of FIG. 3 is configured similarly to the PLL circuit 4 of FIG. 1, and generates the second clock signal having an oscillation frequency not depending on the fluctuation in the power supply voltage.

The sampling pulse generation unit 11 of FIG. 3 generates the START signal and the STOP signal similarly to the frequency divider 5 of FIG. 1. The sampling pulse generation unit 11 generates the START signal and the STOP signal with a light emission timing of the light emitting element as a trigger.

The distance measurement processing unit 12 includes a light receiving unit 21, a time digital converter (TDC) 22, and a histogram generation unit (first histogram generation unit) 23. Although the distance measurement processing unit 12 of FIG. 3 illustrates a configuration in a case where distance measurement is performed by a dToF method, the distance measurement may be performed by a method other than the dToF method, for example, an iToF method, a frequency modulated continuous wave (FMCW) method, or the like. Thus, the distance measurement processing unit 12 may include a light reception information detection unit adaptable to various distance measuring methods. The light reception information detection unit detects timing information at which a reflected light signal is received, and includes the histogram generation unit 23 of FIG. 3. Hereinafter, an example will be described in which the distance measurement is performed by the dToF method.

The light receiving unit 21 includes a light receiving element 21a that receives a reflected light signal from an object. The light receiving element 21a is, for example, a single photon avalanche photo diode (SPAD). The light receiving unit 21 may include a pixel array unit in which a plurality of light receiving elements 21a is arranged in a direction of one dimension or directions in two dimensions.

The time digital converter 22 converts a time difference between a light reception timing of the reflected light signal received by the light receiving element 21a and a light emission timing of a light emitting element (not illustrated in FIG. 3) into a digital signal. The time digital converter 22 includes, for example, a gray code generation unit 22a and a latch group 22b. The gray code generation unit 22a generates a gray code according to the number of second clock signals generated by the PLL circuit 4. The gray code is a code in which a change in the number of transitions between 0 and 1 is minimal. The latch group 22b holds the code generated by the gray code generation unit 22a as a digital signal in synchronization with the light reception timing of the light receiving element 21a.

The histogram generation unit 23 generates a histogram (first histogram) HG1 representing a frequency for each timing when the reflected light signal is received by the light receiving unit 21. In the histogram, as illustrated in FIG. 3, the horizontal axis represents a light reception timing, and the vertical axis represents an appearance frequency. It is indicated that the higher the appearance frequency, the higher the possibility that it is the light reception timing of the reflected light signal.

The histogram correction unit 13 corrects the histogram generated by the distance measurement processing unit 12 on the basis of the jitter detected by the detection unit 1 to generate a corrected histogram RHG. The first histogram HG1 and the corrected histogram RHG are obtained by combining an appearance frequency of the ambient light signal and an appearance frequency of the reflected light signal. Although the appearance frequency of the ambient light signal should be originally uniform, the appearance frequency of the ambient light signal may vary due to the fluctuation in the power supply voltage. Although the appearance frequency of the ambient light signal in the first histogram HG1 is not uniform, the appearance frequency of the ambient light signal in the corrected histogram RHG is corrected to be uniform.

The distance calculation unit 14 measures a distance to the object on the basis of the corrected histogram RHG. More specifically, the distance calculation unit 14 measures the distance to the object on the basis of the time difference between the light reception timing and the light emission timing at which the appearance frequency peaks in the corrected histogram RHG.

As described above, in the distance measuring device 10 of FIG. 3, the histogram is corrected on the basis of the jitter detected by the detection unit 1, so that the histogram can be accurately corrected even if variation occurs in the appearance frequency of the histogram due to the fluctuation in the power supply voltage.

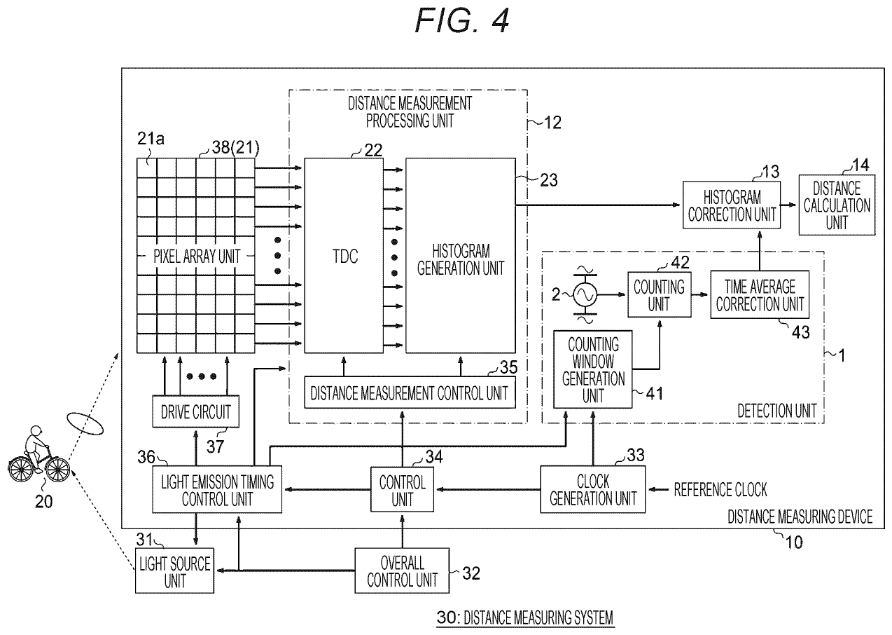

FIG. 4 is a block diagram of a distance measuring system 30 in which the configuration of FIG. 3 is further embodied. In the present specification, the distance measuring system 30 of FIG. 4 may be referred to as an electronic device. The distance measuring system 30 of FIG. 4 includes a light source unit 31, an overall control unit 32, and the distance measuring device 10.

The light source unit 31 includes a plurality of light emitting elements arranged in a direction of one dimension or directions in two dimensions. The plurality of light emitting elements repeatedly emit light signals at predetermined time intervals. The light source unit 31 can scan a predetermined two-dimensional space with the light signals emitted from the plurality of light emitting elements. A specific method of light signal scanning is not limited. The overall control unit 32 controls the light source unit 31 and the distance measuring device 10. Note that a configuration is also conceivable in which the overall control unit 32 is integrated into the distance measuring device 10.

The distance measuring device 10 includes a clock generation unit 33, a control unit 34, a distance measurement control unit 35, the distance measurement processing unit 12, a light emission timing control unit 36, a drive circuit 37, a pixel array unit 38, the detection unit 1, the histogram correction unit 13, and the distance calculation unit 14.

The clock generation unit 33 corresponds to the PLL circuit 4 of FIG. 1. The clock generation unit 33 generates a clock signal having an oscillation frequency not depending on the fluctuation in the power supply voltage by PLL control in synchronization with the reference clock signal. Hereinafter, the clock signal generated by the clock generation unit 33 is referred to as the second clock signal. A frequency of the second clock signal is higher than a frequency of the reference clock signal.

The control unit 34 controls the light emission timing control unit 36 and the distance measurement processing unit 12 in synchronization with the second clock signal. The light emission timing control unit 36 controls a timing at which the light source unit 31 emits a light signal and the drive circuit 37 in accordance with an instruction from the control unit 34. At least two of the control unit 34, the distance measurement control unit 35, or the light emission timing control unit 36 may be integrated.

The light source unit 31 periodically emits light signals from the plurality of light emitting elements in accordance with an instruction from the light emission timing control unit 36. The light signals emitted from the plurality of light emitting elements are light pulse signals having a predetermined pulse width.

The drive circuit 37 drives each light receiving element 21a in the pixel array unit 38. The pixel array unit 38 includes the plurality of light receiving elements 21a arranged in a direction of one dimension or directions in two dimensions. As described above, each light receiving element 21a is, for example, a SPAD. In addition, each light receiving element 21a may include a quench circuit (not illustrated). In the initial state, the quench circuit supplies a reverse bias voltage of a potential difference exceeding a breakdown voltage across the anode and cathode of the SPAD. The drive circuit 37 described above supplies a reverse bias voltage to the SPAD via a corresponding quench circuit after the SPAD detects photons.

The distance measurement processing unit 12 includes the time digital converter 22 (TDC) and the histogram generation unit 23. The time digital converter 22 converts an electric signal according to the reflected light signal received by the pixel array unit 38 into a digital signal. The histogram generation unit 23 generates the histogram (first histogram HG1) representing the appearance frequency for each timing when the reflected light signal is received on the basis of the digital signal converted by the time digital converter 22.

The detection unit 1 of FIG. 4 is substantially the same as the detection unit 1 of FIGS. 1 and 3. The detection unit 1 of FIG. 4 includes the oscillator 2, a counting window generation unit 41, a counting unit 42, and a time average correction unit 43.

Similarly to the oscillator 2 of FIG. 1 or 3, the oscillator 2 of FIG. 4 generates the first clock signal whose oscillation frequency changes according to the fluctuation in the power supply voltage.

The counting window generation unit 41 generates the counting window (first period) on the basis of the second clock signal generated by the clock generation unit 33. The counting window generation unit 41 performs processing similar to that by the latch group 22b of FIG. 3. The counting window has a constant time width that is not affected by the fluctuations in the power supply voltage.

The counting unit 42 counts the time width of the counting window with the first clock signal output from the oscillator 2. The oscillation frequency of the first clock signal changes due to the fluctuation in the power supply voltage, whereas the time width of the counting window is constant without depending on the fluctuation in the power supply voltage. Thus, the count value counted by the counting unit 42 changes due to the fluctuation in the power supply voltage. As described above, the time width of the counting window is counted with the first clock signal, whereby the amount of the fluctuation in the power supply voltage can be detected by the count value.

The time average correction unit 43 corrects the jitter on the basis of the number counted by the counting unit 42. The time average correction unit 43 performs processing similar to that by the time average counting unit 16 and the jitter correction unit 17 of FIG. 3. The time average correction unit 43 may be referred to as a jitter detection unit.

The histogram correction unit 13 corrects the histogram (first histogram HG1) generated by the histogram generation unit 23 on the basis of the jitter corrected by the time average correction unit 43 to generate the corrected histogram RHG. More specifically, the histogram correction unit 13 corrects the histogram so that the appearance frequency for each timing of the ambient light signal received by the light receiving element is constant to generate the corrected histogram RHG. Since variation in the appearance frequency of the ambient light signal is suppressed in the corrected histogram RHG, the distance calculation unit 14 can accurately calculate a distance to an object 20 on the basis of the corrected histogram RHG.

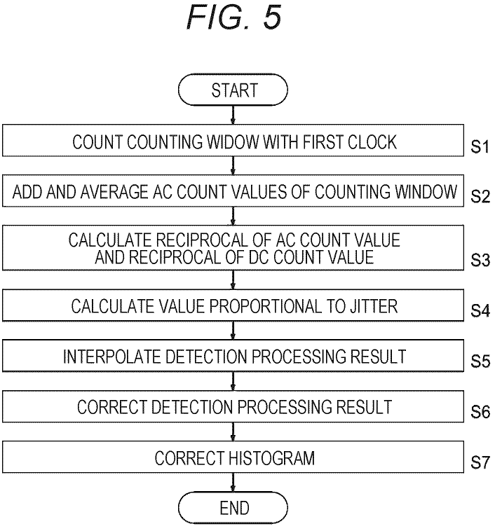

FIG. 5 is a flowchart illustrating processing operation of the distance measuring device 10 according to the first embodiment. First, the counting unit 42 counts the time width of the counting window generated by the counting window generation unit 41 with the first clock signal output from the oscillator 2 (step S1).

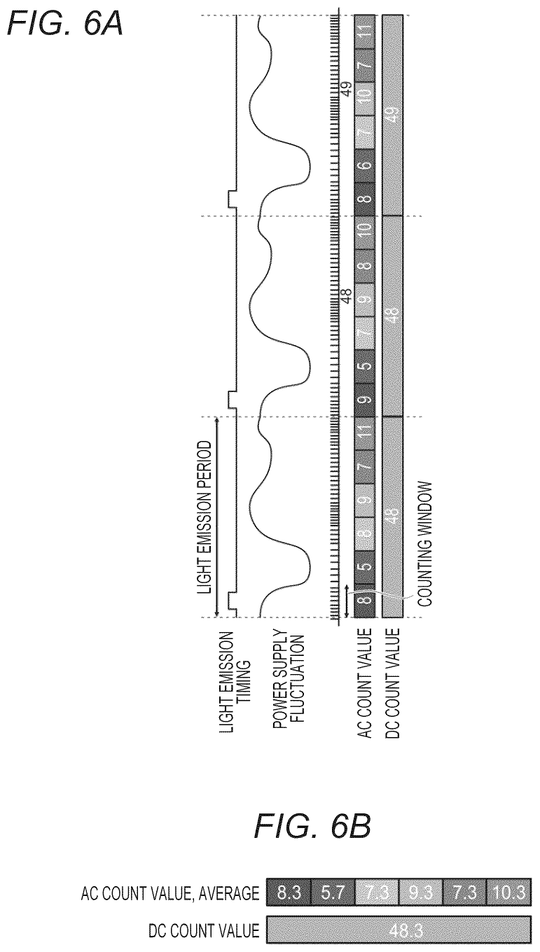

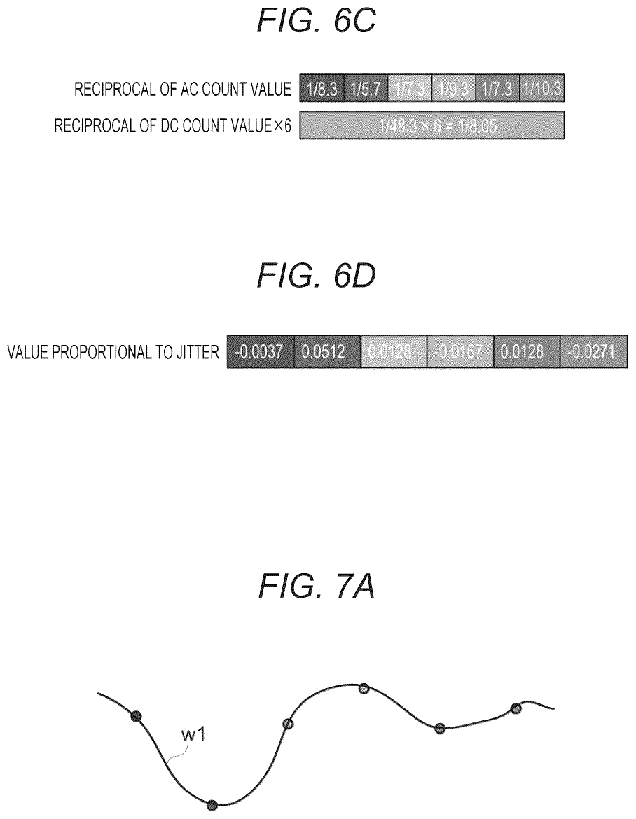

FIG. 6A is a diagram illustrating an example of a light emission period (second period) of the light emitting element in the light source unit 31, the fluctuation in the power supply voltage, and the count value counted by the counting unit 42. A plurality of counting windows is provided within the light emission period of the light emitting element. The counting unit 42 counts the time width of each individual counting window with the first clock signal, and the count value is referred to as an AC count value. In addition, the counting unit 42 counts the time width of the light emission period with the first clock signal, and the count value is referred to as a DC count value. The DC count value is a sum of count values of all counting windows in the light emission period.

FIG. 6A illustrates an example in which light is emitted three times at a certain period, but actually, there are a large number of light emission periods, and the counting unit 42 counts the AC count value and the DC count value for each individual light emission period. As illustrated in FIG. 6A, when the power supply voltage fluctuates within the light emission period, the oscillation frequency of the first clock signal changes. When the oscillation frequency of the first clock signal changes, the number of first clock signals for counting the time width of each individual counting window also changes.

Next, the time average correction unit 43 adds and averages the count values of the counting windows at the same position in each light emission period to remove a quantization error (step S2).

FIG. 6B is a diagram illustrating an example of a processing result in step S2 of FIG. 5. In the example of FIG. 6A, there are six counting windows in one light emission period. In step S2, an average value is calculated of the count values of the nth (n is any integer from one to six in the examples of FIGS. 6A and 6B) counting window in each light emission period. The time average correction unit 43 sets an arithmetic mean value for the six counting windows as the AC count value, and sets an added value for the six AC count values as the DC count value.

Next, a reciprocal of the AC count value added and averaged in step S2 is calculated and set as a new AC count value. In addition, a reciprocal of the DC count value added and averaged in step S2 is calculated, and a value obtained by multiplying the reciprocal of the DC count value by the number of counting windows in an oscillation period is set as a new DC count value (step S3). Since the jitter is proportional to the period, it is possible to acquire a jitter component proportional to the period by calculating the reciprocals of the AC count value and the DC count value.

As described above, the time average correction unit 43 calculates the average value of the count values by the second counting unit counted for each second period and the average value of the count values by the first counting unit counted for each individual first period in the second period, and detects the jitter on the basis of the reciprocal of the average value of the count values by the second counting unit counted for each second period and the reciprocal of the average value of the count values by the first counting unit counted for each individual first period in the second period.

FIG. 6C is a diagram illustrating an example of a processing result in step S3 of FIG. 5. In the example of FIG. 6A, since there are six counting windows in the oscillation period, a value obtained by multiplying the reciprocal of the DC count value calculated in step S2 by six is set as a new DC count value.

Next, a value obtained by subtracting the DC count value from the AC count value calculated in step S3 is set as a value proportional to the jitter (step S4). A calculation result in step S4 is a negative value in a case where the power supply voltage is higher than an average voltage, and is a positive value in a case where the power supply voltage lower than or equal to the average voltage. In the present specification, the processing in step S4 is referred to as detection processing.

FIG. 6D is a diagram illustrating an example of a result of the detection processing in step S4 of FIG. 5. FIG. 6D illustrates values corresponding to six counting windows in one oscillation period. The values of the first, fourth, and sixth counting windows in one oscillation period are negative values, indicating that the power supply voltage was higher than the average voltage in these counting windows. Each numerical value in FIG. 6D is a value proportional to the jitter.

Although a processing result in step S4 may be a final jitter, the frequency characteristics of the detection unit 1 and the distance measurement processing unit 12 of FIG. 4 are not necessarily the same, and thus, in order to correct the frequency characteristic of the jitter obtained in step S4, it is only required to perform processing in steps S5 and S6 below.

In step S5, interpolation processing is performed on the basis of a result of the detection processing in step S4. For the interpolation processing, a known method can be used, and for example, various interpolation processing can be performed such as a bilinear method, a bicubic method, or a spline method.

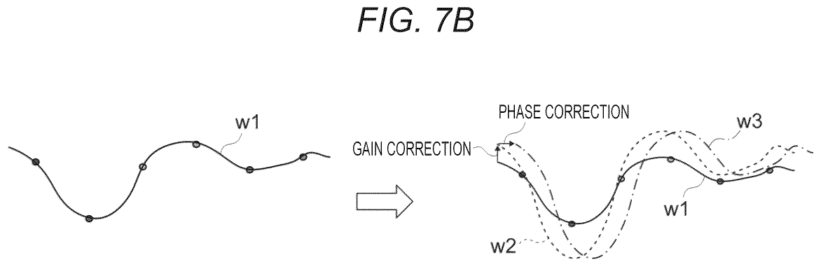

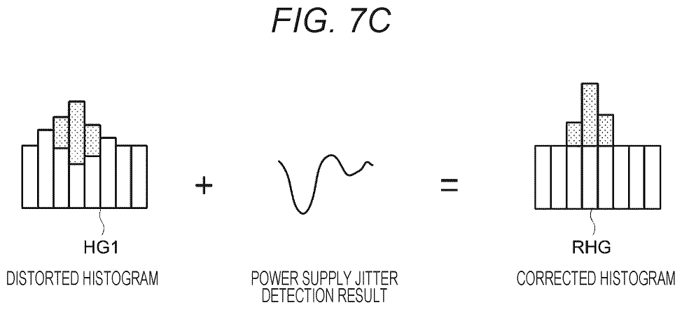

FIG. 7A is a diagram illustrating an example of the interpolation processing. FIG. 7A illustrates an example in which values proportional to the jitter calculated in step S4 of FIG. 5 are plotted, and a curve w1 passing through these plots is generated by the interpolation processing. In the example of FIG. 7A, a plot corresponding to a negative value in FIG. 6D is displayed on the positive side, and a plot corresponding to a positive value is displayed on the negative side. As a result, it can be intuitively understood that the jitter corresponding to the negative value in FIG. 6D is a positive value.

Next, the jitter correction unit 17 corrects the jitter that is a detection processing result (step S6). Here, typically, at least one of amplitude correction for applying a predetermined gain to the curve obtained by the interpolation processing in step S5 or phase correction for shifting the curve obtained by the interpolation processing in step S5 in the time axis direction is performed. Alternatively, a digital filter may be applied to the curve obtained by the interpolation processing in step S5. With the processing in step S6, jitter correction processing (detection processing) ends.

FIG. 7B is a diagram illustrating an example of the jitter correction processing. FIG. 7B illustrates a curve w2 obtained by performing the amplitude correction on the curve w1 of FIG. 7A and a curve w3 obtained by performing the phase correction.

The processing in steps S5 and S6 of FIG. 5 is effective when there is a difference between the frequency characteristic of the detection unit 1 and the frequency characteristic of the distance measurement processing unit 12.

Next, the histogram correction unit 13 corrects the histogram (first histogram HG1) generated by the histogram generation unit 23 on the basis of the jitter corrected in step S6 to generate the corrected histogram RHG (step S7).

FIG. 7C is a diagram schematically illustrating processing of correcting the first histogram HG1. The first histogram HG1 includes an ambient light signal component and a reflected light signal component, and the ambient light signal component should originally have a uniform appearance frequency. However, when the power supply voltage fluctuates, variation occurs in the appearance frequency of the ambient light signal component. The variation in the ambient light signal component of the first histogram HG1 has correlation with the jitter. Thus, by correcting the variation of the ambient light signal component of the first histogram HG1 on the basis of the jitter, it is possible to make the appearance frequency of the ambient light signal component uniform, and obtain the corrected histogram RHG with high reliability.

As described above, in the first embodiment, the fixed time width of the counting window is counted with the first clock signal in which the oscillation frequency changes according to the fluctuation in the power supply voltage, and the reciprocal of the count value is taken to detect and correct the jitter. Since the first histogram HG1 generated by the histogram generation unit 23 is corrected on the basis of the corrected jitter, the ambient light signal component included in the first histogram HG1 is not affected by the fluctuation in the power supply voltage, the corrected histogram RHG with high reliability can be generated, and it is possible to improve the distance measurement accuracy by calculating the distance to the object 20 by using the corrected histogram RHG.

### Second Embodiment

A second embodiment differs from the first embodiment in how the corrected jitter is used.

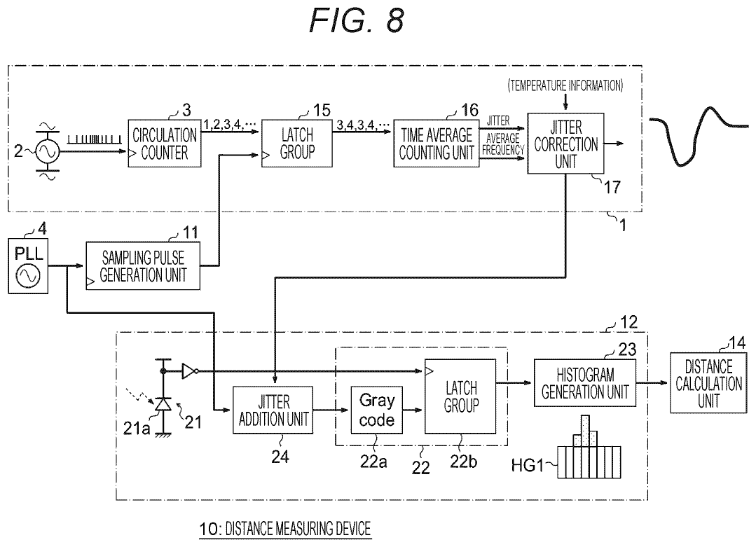

FIG. 8 is a block diagram illustrating a schematic configuration of the distance measuring device 10 according to the second embodiment. As in FIG. 3, the distance measuring device 10 of FIG. 8 includes the detection unit 1, the PLL circuit 4, the sampling pulse generation unit 11, the distance measurement processing unit 12, and the distance calculation unit 14.

The distance measuring device 10 of FIG. 8 is not provided with the histogram correction unit 13 of FIG. 3. The detection unit 1 of FIG. 8 performs processing similar to that by the detection unit 1 of FIG. 3 to detect the jitter by using the counting window, and then performs at least one of the amplitude correction or the phase correction to correct the jitter.

The distance measurement processing unit 12 of FIG. 8 includes the light receiving unit 21, the time digital converter 22 (TDC), and the histogram generation unit 23, similarly to the distance measurement processing unit 12 of FIG. 3, and in addition, includes a jitter addition unit 24 that does not exist in the distance measurement processing unit 12 of FIG. 3.

The jitter addition unit 24 controls timings of at least some signals from when the light receiving element 21a receives the reflected light signal to when the histogram generation unit 23 generates the histogram HG1 on the basis of the jitter detected by the detection unit 1. FIG. 8 illustrates an example in which the second clock signal generated by the PLL circuit 4 is input to the jitter addition unit 24. In this example, the jitter addition unit 24 adjusts at least one of the oscillation frequency or the phase of the second clock signal.

The gray code generation unit 22a in the time digital converter 22 of FIG. 8 generates a gray code on the basis of the second clock signal of which at least one of the oscillation frequency or the phase is adjusted by the jitter addition unit 24. As a result, the digital signal in which the jitter is adjusted can be output from the time digital converter 22. Thus, the histogram generation unit 23 of FIG. 8 can generate the first histogram HG1 having uniform ambient light signal components.

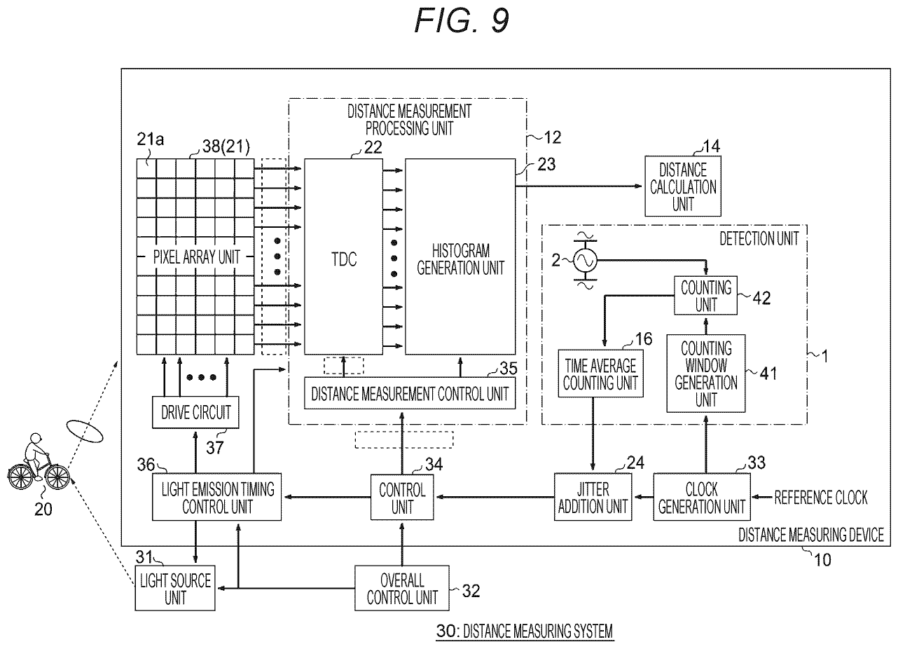

FIG. 9 is a block diagram of the distance measuring system 30 in which the configuration of FIG. 8 is further embodied. In the present specification, the distance measuring system 30 of FIG. 9 may be referred to as an electronic device. In FIG. 9, the same components as those in FIG. 4 are denoted by the same reference numerals.

The distance measuring system 30 of FIG. 9 includes the light source unit 31, the overall control unit 32, and the distance measuring device 10 as in FIG. 4. The distance measuring device 10 of FIG. 9 is different from the distance measuring device 10 of FIG. 4 in a part of the internal configuration. The distance measuring device 10 of FIG. 9 includes the jitter addition unit 24 that does not exist in the distance measuring device 10 of FIG. 4. On the other hand, the distance measuring device 10 of FIG. 9 does not include the histogram correction unit 13 in the distance measuring device 10 of FIG. 4.

The jitter addition unit 24 in the distance measuring device 10 of FIG. 9 is arranged between the clock generation unit 33 and the control unit 34, and controls at least one of the oscillation frequency or the phase of the second clock signal generated by the clock generation unit 33. The control unit 34 controls the light emission timing control unit 36 and the distance measurement control unit 35 in synchronization with the second clock signal of which at least one of the oscillation frequency or the phase is controlled by the jitter addition unit 24.

In FIG. 9, the jitter addition unit 24 is arranged between the clock generation unit 33 and the control unit 34, but the jitter addition unit 24 may be arranged in a place different from that in FIG. 9. For example, the jitter addition unit 24 may be arranged in any of places indicated by a broken line frame in FIG. 9.

A first modification of the arrangement place of the jitter addition unit 24 is between the control unit 34 and the distance measurement control unit 35. In this case, the control unit 34 controls a timing of a control signal for controlling the distance measurement control unit 35 on the basis of the jitter detected by the detection unit 1.

A second modification of the arrangement place of the jitter addition unit 24 is between the distance measurement control unit 35 and the time digital converter 22. In this case, the distance measurement control unit 35 controls a timing of a control signal for controlling the time digital converter 22 on the basis of the jitter detected by the detection unit 1.

A third modification of the arrangement place of the jitter addition unit 24 is between the pixel array unit 38 and the time digital converter 22. From the pixel array unit 38, electric signals according to the reflected light signal are output for respective pixel rows, for example. Timings of these multiple electric signals are controlled on the basis of the jitter detected by the detection unit 1.

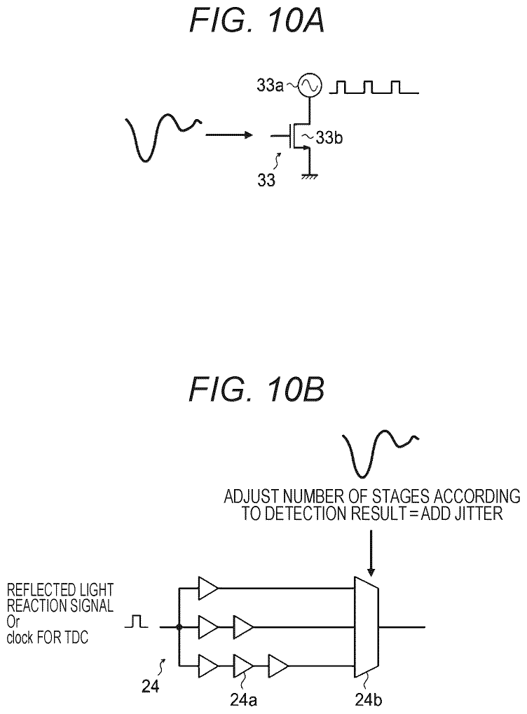

FIG. 10A is a diagram illustrating a first example of a specific configuration of the jitter addition unit 24. The jitter addition unit 24 of FIG. 10A controls a current source 33b that generates a current to be supplied to an oscillator 33a in the clock generation unit 33 with the jitter detected by the detection unit 1. The current source 33b controls a current to be supplied to the oscillator 2 on the basis of the jitter detected by the detection unit 1. As a result, it is possible to control at least one of the oscillation frequency or the phase of the second clock signal output from the oscillator 2.

Note that FIG. 10A illustrates an example in which the current source 33b is constituted by one NMOS transistor, but any specific configuration of the current source 33b can be used, and the current source 33b may be formed including at least one of a variable resistance element, a variable inductor element, or a variable capacitance element, and at least one of the resistance value, the inductance, or the capacitance may be controlled on the basis of the jitter detected by the detection unit 1.

FIG. 10B is a diagram illustrating a second example of the specific configuration of the jitter addition unit 24. The jitter addition unit 24 of FIG. 10B includes a plurality of delay circuits 24a and a selector 24b. The plurality of delay circuits 24a delays a signal to which the jitter is to be added by different delay times, respectively. The selector 24b selects one delay circuit 24a from the plurality of delay circuits 24a on the basis of the jitter detected by the detection unit 1, and delays the signal for handling the addition of the jitter.

The specific configuration of the jitter addition unit 24 is not limited to those illustrated in FIGS. 10A and 10B. For example, the power supply voltage of at least one of the clock generation unit 33, the control unit 34, the distance measurement control unit 35, or the pixel array unit 38 may be controlled on the basis of the jitter detected by the detection unit 1.

As described above, in the second embodiment, the time width of the counting window is counted with the first clock signal in which the oscillation frequency changes due to the fluctuation in the power supply voltage to detect the jitter, and the timing of the control signal in the distance measuring device 10 is controlled by the detected jitter. As a result, it is possible to generate a histogram having a uniform appearance frequency due to the ambient light signal component without correcting the histogram, and to improve distance measurement accuracy.

### Third Embodiment

In a third embodiment, a histogram (second histogram HG2) based on an ambient light signal not including a reflected light signal is generated.

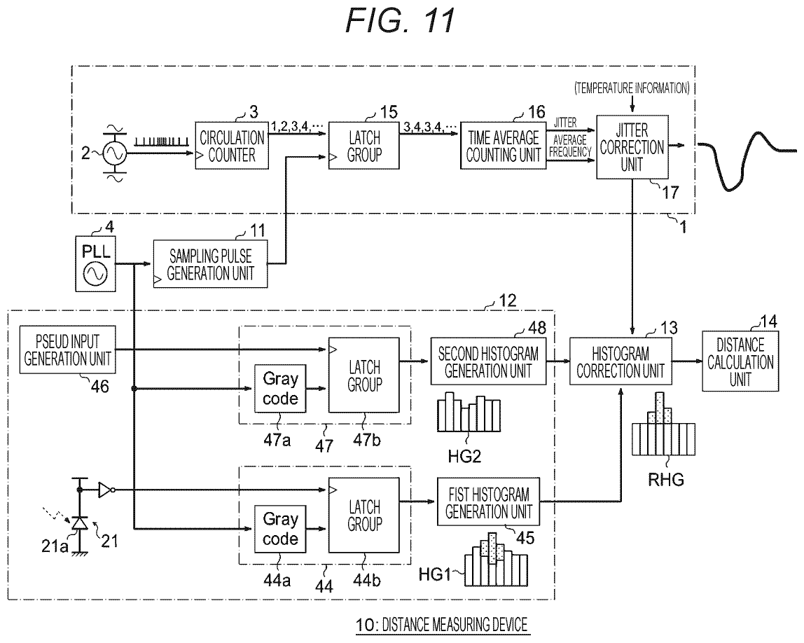

FIG. 11 is a block diagram illustrating a schematic configuration of the distance measuring device 10 according to the third embodiment. As in FIG. 3, the distance measuring device 10 of FIG. 11 includes the detection unit 1, the PLL circuit 4, the sampling pulse generation unit 11, the distance measurement processing unit 12, the histogram correction unit 13, and the distance calculation unit 14.

The detection unit 1 of FIG. 11 performs processing similar to that by the detection unit 1 of FIG. 3 to detect the jitter by using the counting window, and then corrects the jitter.

The distance measurement processing unit 12 of FIG. 11 has a configuration related to distance measurement processing for a pseudo input signal in addition to the configuration of the distance measurement processing unit 12 of FIG. 3. More specifically, the distance measurement processing unit 12 of FIG. 11 includes the light receiving unit 21, a first time digital converter 44, a first histogram generation unit 45, a pseudo input generation unit 46, a second time digital converter 47, and a second histogram generation unit 48.

The light receiving unit 21, the first time digital converter 44, and the first histogram generation unit 45 in the distance measurement processing unit 12 of FIG. 11 perform processing operation similar to that of the light receiving unit 21, the time digital converter 22, and the histogram generation unit 23 in the distance measurement processing unit 12 of FIG. 3. That is, the first time digital converter 44 generates the first digital signal according to the reflected light signal. The first histogram generation unit 45 generates the first histogram HG1 representing the appearance frequency for each timing at which the reflected light signal is received.

The pseudo input generation unit 46 in the distance measurement processing unit 12 of FIG. 11 generates an electric signal in a case where it is assumed that the ambient light signal not including the reflected light signal is received. The electric signal is referred to as a pseudo input signal. The second time digital converter 47 converts the pseudo input signal into a second digital signal. The second histogram generation unit 48 generates the second histogram HG2 representing the appearance frequency for each timing at which the ambient light signal is received.

The histogram correction unit 13 corrects the first histogram HG1 on the basis of the jitter detected by the detection unit 1 and the second histogram HG2 to generate the corrected histogram RHG. The distance calculation unit 14 measures the distance to the object 20 on the basis of the corrected histogram RHG.

The pseudo input signal is an electric signal corresponding to the ambient light signal not including the reflected light signal. Thus, in the second histogram HG2 corresponding to the pseudo input signal, the appearance frequency should originally be uniform. However, in practice, variation occurs in the appearance frequency of the second histogram HG2 due to the fluctuation in the power supply voltage. Thus, the histogram correction unit 13 according to the present embodiment corrects the first histogram HG1 on the basis of the jitter detected by the detection unit 1 and the second histogram HG2.

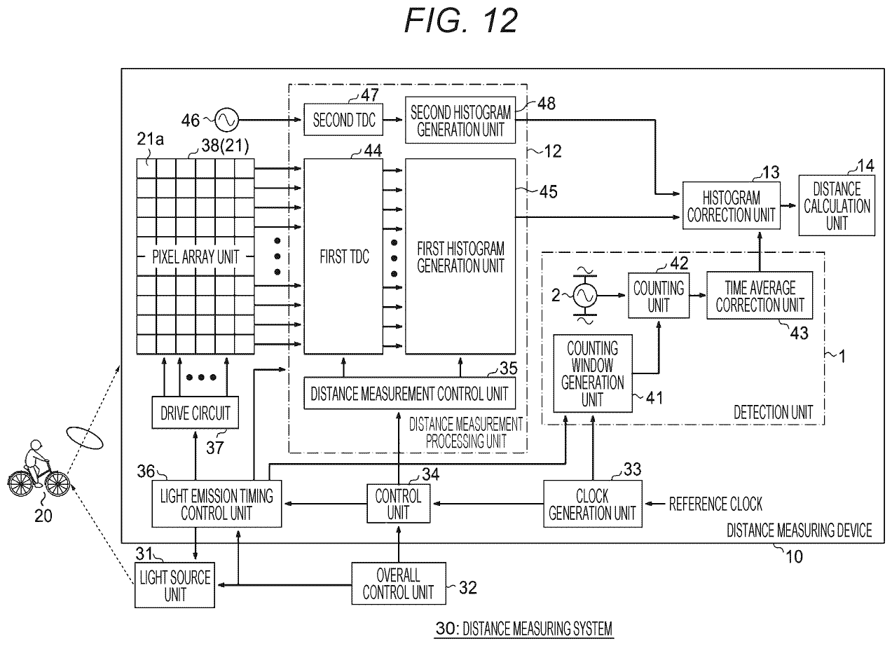

FIG. 12 is a block diagram of the distance measuring system 30 in which the configuration of FIG. 11 is further embodied. In the present specification, the distance measuring system 30 of FIG. 12 may be referred to as an electronic device. In FIG. 12, the same components as those in FIG. 4 are denoted by the same reference numerals.

The distance measuring system 30 of FIG. 12 includes the light source unit 31, the overall control unit 32, and the distance measuring device 10 as in FIG. 4. As in FIG. 4, the distance measuring device 10 of FIG. 12 includes the clock generation unit 33, the control unit 34, the distance measurement control unit 35, the distance measurement processing unit 12, the light emission timing control unit 36, the drive circuit 37, the pixel array unit 38, the detection unit 1, the histogram correction unit 13, and the distance calculation unit 14.

The internal configuration of the distance measurement processing unit 12 in the distance measuring device 10 of FIG. 12 is partially different from that of the distance measurement processing unit 12 of FIG. 4. The internal configuration of the distance measuring device 10 other than that is similar to that in FIG. 4.

The distance measurement processing unit 12 of FIG. 12 includes the first time digital converter 44, the first histogram generation unit 45, the pseudo input generation unit 46, the second time digital converter 47, and the second histogram generation unit 48. The first time digital converter 44 and the first histogram generation unit 45 in the distance measurement processing unit 12 of FIG. 12 perform processing similar to that of the time digital converter 22 and the histogram generation unit 23 in the distance measurement processing unit 12 of FIG. 4. The distance measurement processing unit 12 of FIG. 12 includes the pseudo input generation unit 46, the second time digital converter 47, and the second histogram generation unit 48 in addition to the internal configuration of the distance measurement processing unit 12 of FIG. 4.

The second time digital converter 47 converts the pseudo input signal into the second digital signal. The second histogram generation unit 48 generates the second histogram HG2 representing the appearance frequency for each timing at which the ambient light signal is received.

The histogram correction unit 13 in the distance measuring device 10 of FIG. 12 corrects the first histogram HG1 on the basis of the jitter detected by the detection unit 1 and the second histogram HG2 to generate the corrected histogram RHG. As a result, the appearance frequency of the corrected histogram RHG does not fluctuate depending on the ambient light signal component, and the reflected light signal component can be faithfully extracted. Thus, accuracy of distance measurement in the distance calculation unit 14 can be improved.

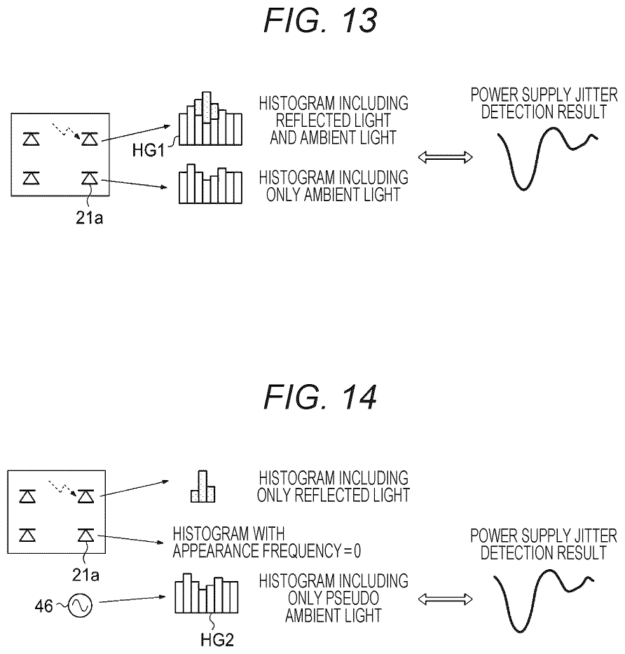

In the light receiving unit 21 in the distance measuring system 30 of FIG. 12, the light receiving element 21a that has received the reflected light signal receives a signal including both the reflected light signal and the ambient light signal, so that the first histogram HG1 generated by the first histogram generation unit 45 has a shape as illustrated in FIG. 13. The first histogram HG1 of FIG. 13 includes the ambient light signal component and the reflected light signal component, and in both the ambient light signal component and the reflected light signal component, the appearance frequency fluctuates due to the fluctuation in the power supply voltage. Note that the first histogram generation unit 45 can generate a first histogram corresponding to a signal including the reflected light signal and the ambient light signal, a signal including only the ambient light signal, or a reflected light signal not including the ambient light signal. That is, the first histogram generation unit 45 can generate the first histogram in a pseudo manner on the basis of the signal including only the ambient light signal.

On the other hand, the pseudo input generation unit 46 inputs the pseudo input signal corresponding to the ambient light signal not including the reflected light signal to the second time digital converter 47. Since the pseudo input signal is affected by the fluctuation in the power supply voltage, in the second histogram HG2 generated by the second histogram generation unit 48, the appearance frequency changes in synchronization with the fluctuation in the power supply voltage as illustrated in FIG. 13.

Since the second histogram HG2 and the jitter detected by the detection unit 1 fluctuate in synchronization with the fluctuation in the power supply voltage, the histogram correction unit 13 can generate the corrected histogram RHG so that the appearance frequency of the ambient light signal component included in the first histogram HG1 is uniform by comparing the second histogram HG2 and the jitter with each other.

In a case where the distance between the distance measuring device 10 and the object 20 is short or in a case where a signal intensity of the reflected light signal is much larger than a signal intensity of the ambient light signal, the ambient light signal can be ignored when the light receiving element 21a receives the reflected light signal. In this case, as illustrated in FIG. 14, the first histogram HG1 substantially includes only the reflected light signal component. The second histogram HG2 based on the pseudo input signal input to the pseudo input generation unit 46 is the same as the second histogram HG2 of FIG. 13.

Also in the case of FIG. 14, the histogram correction unit 13 can generate the corrected histogram RHG in which the appearance frequency of the ambient light signal component included in the first histogram HG1 is uniform on the basis of the jitter detected by the detection unit 1 and the second histogram HG2.

As described above, in the third embodiment, by providing the pseudo input generation unit 46, it is possible to simply grasp the fluctuation in the appearance frequency of the second histogram HG2 based on the ambient light signal, and easily correct the ambient light signal component included in the first histogram HG1 generated when the reflected light signal is received, and as a result, it is possible to generate the corrected histogram RHG that is not affected by the variation in the power supply voltage, and accurately measure the distance to the object 20.

### Fourth Embodiment

In a fourth embodiment, the configuration of the distance measuring system 30 according to the third embodiment is simplified.

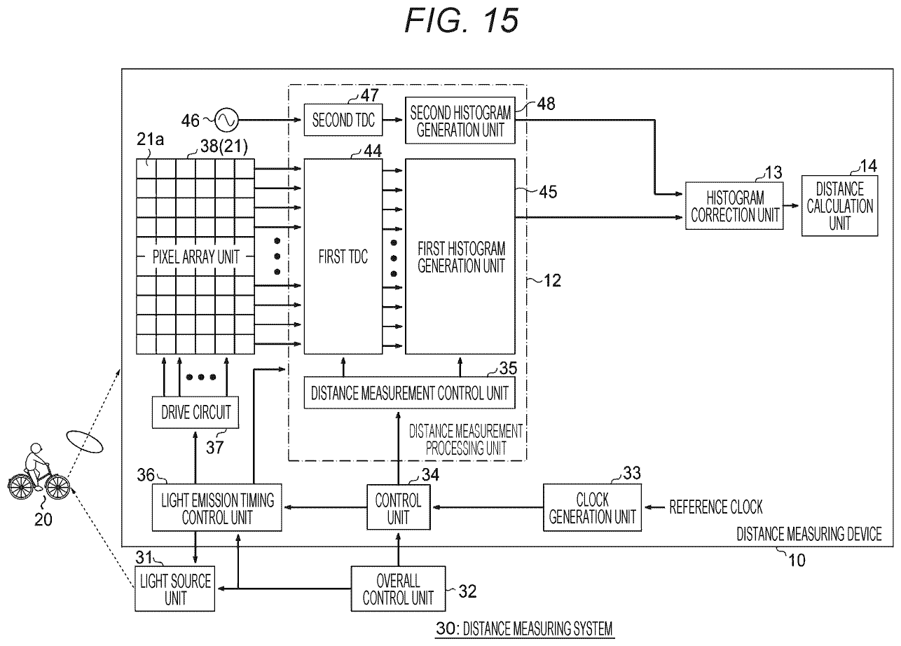

FIG. 15 is a block diagram illustrating an internal configuration of the distance measuring system 30 according to the fourth embodiment. In the present specification, the distance measuring system 30 of FIG. 15 may be referred to as an electronic device. In FIG. 15, the same components as those in FIG. 12 are denoted by the same reference numerals.

The distance measuring system 30 of FIG. 15 has a configuration in which the detection unit 1 in the distance measuring system 30 of FIG. 12 is omitted. The distance measuring system 30 of FIG. 15 is configured similarly to the distance measuring system 30 of FIG. 12 except that the detection unit 1 does not exist.

The distance measuring device 10 in the distance measuring system 30 of FIG. 15 includes the first time digital converter 44, the first histogram generation unit 45, the pseudo input generation unit 46, the second time digital converter 47, and the second histogram generation unit 48, similarly to the distance measuring device 10 of FIG. 12.

The histogram correction unit 13 of FIG. 12 corrects the first histogram HG1 on the basis of the second histogram HG2 and the jitter detected by the detection unit 1. On the other hand, the histogram correction unit 13 of FIG. 14 corrects the first histogram HG1 on the basis of the second histogram HG2. More specifically, the histogram correction unit 13 corrects the first histogram HG1 so that the appearance frequency of the ambient light signal component is uniform to generate the corrected histogram RHG.

As described above, in the fourth embodiment, the second histogram HG2 by the pseudo input signal is generated and the first histogram HG1 is corrected without detecting the jitter due to the fluctuation in the power supply voltage, so that the corrected histogram RHG can be generated with a simple configuration as compared with the third embodiment.

### Fifth Embodiment

In a case where an area of the pixel array unit 38 is large, the amount of the fluctuation in the power supply voltage may vary depending on the arrangement place of the pixel. Thus, the pixel array unit 38 may be divided into a plurality of pixel groups, and the detection unit 1 according to the first to fourth embodiments may be provided for each pixel group to correct the first histogram HG1.

In addition, in the case where the area of the pixel array unit 38 is large, the signal intensity of the ambient light signal may vary depending on the arrangement place of the pixel. Thus, the pseudo input generation unit 46, the second time digital converter 47, and the second histogram generation unit 48 may be provided at a plurality of locations in the pixel array unit 38.

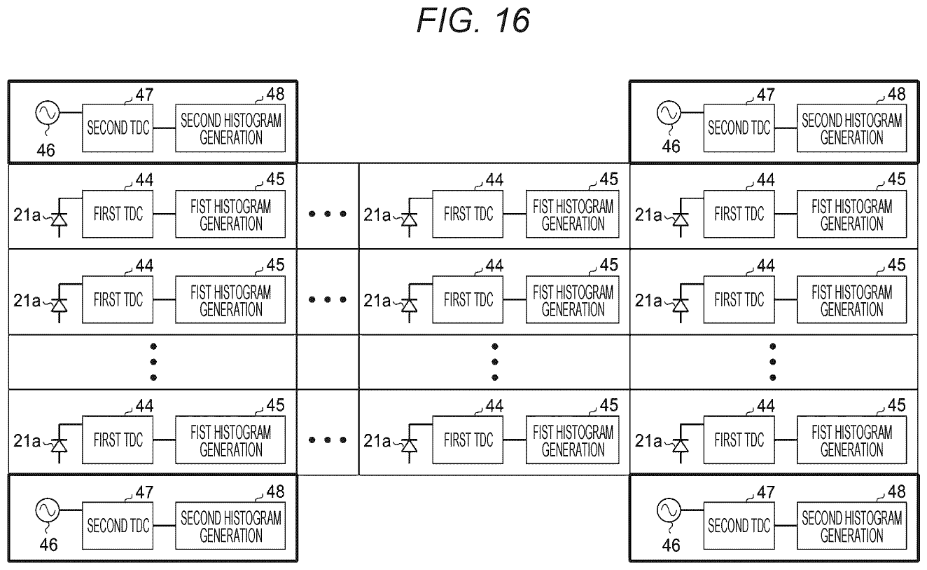

FIG. 16 is a layout diagram illustrating an example in which the pseudo input generation unit 46, the second time digital converter 47, and the second histogram generation unit 48 are arranged at four corners of the pixel array unit 38. FIG. 16 is an example, and any arrangement place and any number of arrangements are adopted of the pseudo input generation unit 46, the second time digital converter 47, and the second histogram generation unit 48.

As described above, in a fifth embodiment, in a case where the area of the pixel array unit 38 is large and the amount of the fluctuation in the power supply voltage in the plane varies, the detection unit 1 can be provided at a plurality of locations in the pixel array unit 38, or the pseudo input generation unit 46, the second time digital converter 47, and the second histogram generation unit 48 can be arranged at a plurality of locations in the pixel array unit 38. As a result, it is possible to suppress variation in the distance measurement accuracy in a case where the reflected light signal is received by the pixel at any place in the pixel array unit 38.

### <<Application Example>>

The technology according to the present disclosure can be applied to various products. For example, the technology according to the present disclosure may also be implemented as a device mounted on any kind of mobile body such as an automobile, an electric automobile, a hybrid electric automobile, a motorcycle, a bicycle, a personal mobility, an airplane, a drone, a ship, a robot, a construction machine, an agricultural machine (tractor), or the like.

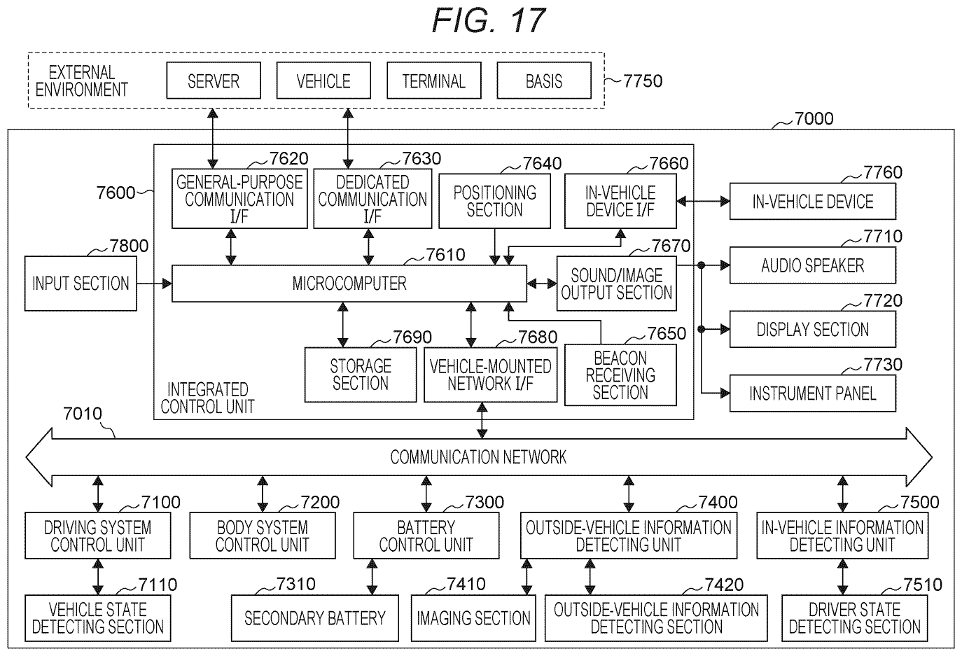

FIG. 17 is a block diagram illustrating a schematic configuration example of a vehicle control system 7000 as an example of a mobile body control system to which the technology of the present disclosure is applied. The vehicle control system 7000 includes a plurality of electronic control units connected to each other via a communication network 7010. In the example illustrated in FIG. 17, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. A functional configuration of the integrated control unit 7600 illustrated in FIG. 17 includes a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

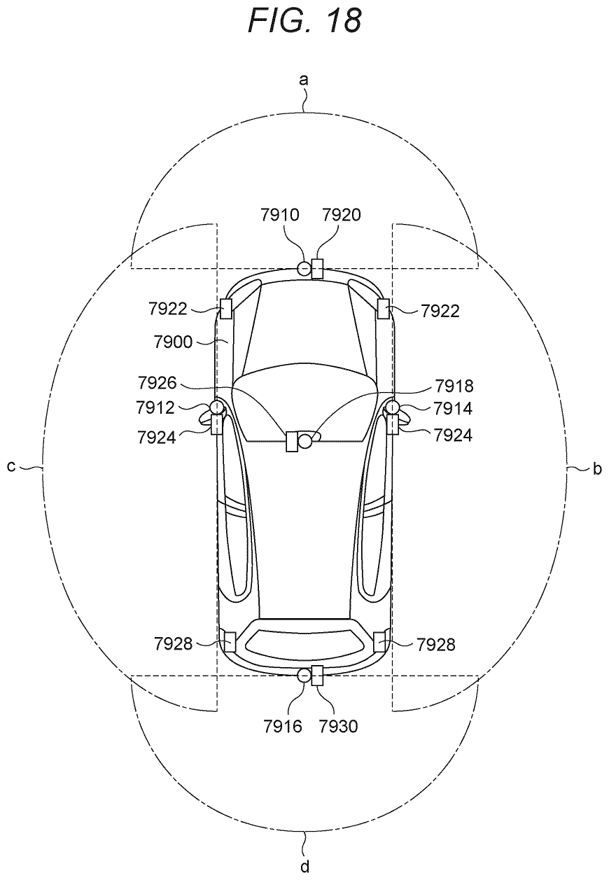

Here, FIG. 18 illustrates an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Note that FIG. 18 illustrates an example of the imaging range of each of the imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Referring back to FIG. 17, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example of FIG. 17, an audio speaker 7710, a display section 7720, and an instrument panel 7730 are illustrated as the output device. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Note that, in the example illustrated in FIG. 17, at least two control units connected through the communication network 7010 may be integrated as one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

Note that, a computer program for implementing each function of the distance measuring system 30 according to the present embodiment described with reference to FIG. 4 and the like can be implemented in any of the control units or the like. In addition, a computer-readable recording medium in which such a computer program is stored can be provided. The recording medium is, for example, a magnetic disk, an optical disk, a magneto-optical disk, a flash memory, or the like. In addition, the computer program described above may be distributed via, for example, a network without using a recording medium.

In the vehicle control system 7000 described above, the distance measuring system 30 according to the present embodiment described with reference to FIG. 4 and the like can be applied to the integrated control unit 7600 of an application example illustrated in FIG. 17. For example, processing operation of at least one of the detection unit 1, the distance measurement processing unit 12, the control unit 34, or the overall control unit 32 of the distance measuring system 30 can be performed by the microcomputer 7610, the storage section 7690, and the vehicle-mounted network I/F 7680 of the integrated control unit 7600.

In addition, at least some of the components of the distance measuring system 30 described with reference to FIG. 4 and the like may be implemented in a module (for example, an integrated circuit module including one die) for the integrated control unit 7600 illustrated in FIG. 17. Alternatively, the distance measuring system 30 described with reference to FIG. 4 and the like may be implemented by a plurality of control units of the vehicle control system 7000 illustrated in FIG. 17.

Note that the present technology can have the following configurations.

(1) A distance measuring device including:
an oscillator that generates a first clock signal whose oscillation frequency changes according to fluctuation in a power supply voltage;
a first counting unit that repeats operation of counting the number of the first clock signals in a first period set in advance a plurality of times;
a jitter detection unit that performs averaging processing of count values for the plurality of times by the first counting unit to detect jitter due to the fluctuation in the power supply voltage;
a light receiving element that emits a light signal to an object and receives a reflected light signal from the object every second period including a plurality of the first periods;
a light reception information detection unit that detects timing information at which the reflected light signal is received; and
a distance calculation unit that measures a distance to the object on the basis of the timing information detected by the light reception information detection unit.

(2) The distance measuring device according to (1), in which the light reception information detection unit generates a first histogram representing an appearance frequency for each of timings at which the reflected light signal is received.

(3) The distance measuring device according to (1) or (2), in which the first period is a fixed period.

(4) The distance measuring device according to any one of (1) to (3), in which the jitter detection unit calculates a difference between a count value by the first counting unit acquired at a timing of a start of the first period and a count value by the first counting unit acquired at a timing of an end of the first period a plurality of times, and averages a plurality of the differences.

(5) The distance measuring device according to any one of (1) to (4), further including
a second counting unit that repeats operation of counting the number of the first clock signals in the second period a plurality of times, in which
the jitter detection unit calculates an average value of count values by the second counting unit counted for each of the second periods and an average value of count values by the first counting unit counted for each of the individual first periods in the second period, and detects the jitter on the basis of a reciprocal of the average value of the count values by the second counting unit counted for each of the second periods and a reciprocal of the average value of the count values by the first counting unit counted for each of the individual first periods in the second period.

(6) The distance measuring device according to (2), further including
a histogram correction unit that corrects the first histogram on the basis of the jitter detected by the jitter detection unit to generate a corrected histogram, in which
the distance calculation unit measures the distance to the object on the basis of the corrected histogram.

(7) The distance measuring device according to (6), in which the histogram correction unit corrects the first histogram such that an appearance frequency for each of timings of an ambient light signal received by the light receiving element is constant to generate the corrected histogram.

(8) The distance measuring device according to (6) or (7), further including:
a first time digital converter that generates a first digital signal according to the reflected light signal received by the light receiving element;
a pseudo input generation unit that generates a pseudo input signal according to an ambient light signal not including the reflected light signal;
a second time digital converter that converts the pseudo input signal into a second digital signal; and
a second histogram generation unit that generates a second histogram representing an appearance frequency for each of timings at which the ambient light signal is received, in which
the light reception information detection unit generates the first histogram on the basis of the first digital signal, and
the histogram correction unit corrects the first histogram on the basis of the jitter detected by the jitter detection unit and the second histogram to generate the corrected histogram.

(9) The distance measuring device according to (8), in which the light reception information detection unit generates the first histogram corresponding to a signal including the reflected light signal and the ambient light signal, a signal including only the ambient light signal, or the reflected light signal not including the ambient light signal.

(10) The distance measuring device according to (9), in which the light reception information detection unit generates the first histogram in a pseudo manner on the basis of the signal including only the ambient light signal.

(11) The distance measuring device according to any one of (6) to (10), further including
a jitter correction unit that corrects a frequency characteristic of the jitter detected by the jitter detection unit, in which
the histogram correction unit corrects the first histogram on the basis of the jitter corrected by the jitter correction unit to generate the corrected histogram.

(12) The distance measuring device according to (11), in which the jitter correction unit corrects at least one of an amplitude or a phase of the jitter detected by the jitter detection unit.

(13) The distance measuring device according to (11) or (12), in which the jitter correction unit corrects at least one of an amplitude or a phase of the jitter detected by the jitter detection unit, on the basis of temperature information and the jitter detected by the jitter detection unit.

(14) The distance measuring device according to (2), further including a jitter addition unit that controls timings of at least some signals from when the light receiving element receives the reflected light signal to when the light reception information detection unit generates the first histogram on the basis of the jitter detected by the jitter detection unit.

(15) The distance measuring device according to (14), further including:
a clock generation unit that generates a second clock signal having an oscillation frequency not depending on the fluctuation in the power supply voltage, on the basis of a reference clock signal;
a counting window generation unit that generates the first period in synchronization with the second clock signal; and
a light emission timing control unit that controls a light emission timing of a light emitting element that emits the light signal in synchronization with the second clock signal.

(16) The distance measuring device according to (15), in which
the jitter addition unit adds the jitter to the second clock signal, and
the light emission timing control unit controls the light emission timing of the light emitting element that emits the light signal in synchronization with the second clock signal to which the jitter is added.

(17) The distance measuring device according to (16), in which the jitter addition unit controls at least one of an oscillation frequency or a phase of the second clock signal on the basis of the jitter detected by the jitter detection unit.

(18) The distance measuring device according to (14), further including:
a clock generation unit that generates a second clock signal having an oscillation frequency not depending on the fluctuation in the power supply voltage, on the basis of a reference clock signal;
a first time digital converter that generates a first digital signal according to the reflected light signal;
a first control unit that controls the first time digital converter and the light reception information detection unit;
a second control unit that controls the first control unit in synchronization with the second clock signal; and
a pixel array unit including a plurality of the light receiving elements, in which
the jitter addition unit adds the jitter to at least one of a plurality of electric signals according to a plurality of the reflected light signals output from the plurality of the light receiving elements in the pixel array unit, a first control signal for controlling the first control unit, or a second control signal that is output from the second control unit and is for controlling the first control unit.

(19) A distance measuring device including:
a light receiving element that emits a light signal to an object and receives a reflected light signal from the object every second period including a plurality of first periods;
a first time digital converter that generates a first digital signal according to the reflected light signal;
a first histogram generation unit that generates a first histogram representing an appearance frequency for each of timings at which the reflected light signal is received;
a pseudo input generation unit that generates a pseudo input signal according to an ambient light signal not including the reflected light signal;
a second time digital converter that converts the pseudo input signal into a second digital signal;
a second histogram generation unit that generates a second histogram representing an appearance frequency for each of timings at which the ambient light signal is received;
a histogram correction unit that corrects the first histogram on the basis of the second histogram to generate a corrected histogram; and
a distance calculation unit that measures a distance to the object on the basis of the corrected histogram.

(20) The distance measuring device according to any one of (8), (9), and (19), further including
a pixel array unit including a plurality of the light receiving elements, in which
a plurality of the pseudo input generation units and a plurality of the second time digital converters are provided in association with two or more of the light receiving elements arranged separately in the pixel array unit.

Aspects of the present disclosure are not limited to the above-described individual embodiments, but include various modifications that can be conceived by those skilled in the art, and the effects of the present disclosure are not limited to the above-described contents. That is, various additions, modifications, and partial deletions are possible without departing from the conceptual idea and spirit of the present disclosure derived from the matters defined in the claims and equivalents thereof.

### REFERENCE SIGNS LIST

1 Detection unit
2 Oscillator
3 Circulation counter
4 PLL circuit
5 Frequency divider
6 First latch circuit
7 Second latch circuit
8 Synchronization processing unit
10 Distance measuring device
11 Sampling pulse generation unit
12 Distance measurement processing unit
13 Histogram correction unit
14 Distance calculation unit
15 Latch group
16 Time average counting unit
17 Jitter correction unit
20 Object
21 Light receiving unit
21a Light receiving element
22 Time digital converter
22a Gray code generation unit
22b Latch group
23 Histogram generation unit
24 Jitter addition unit
24a Delay circuit
24b Selector
30 Distance measuring system
31 Light source unit
32 Overall control unit
33 Clock generation unit
33a Oscillator
33b Current source
34 Control unit
35 Distance measurement control unit
36 Light emission timing control unit
37 Drive circuit
38 Pixel array unit
41 Counting window generation unit
42 Counting unit
43 Time average correction unit
44 First time digital converter
45 First histogram generation unit
46 Pseudo input generation unit
47 Second time digital converter
48 Second histogram generation unit

1. A distance measuring device comprising:
an oscillator that generates a first clock signal whose oscillation frequency changes according to fluctuation in a power supply voltage;
a first counting unit that repeats operation of counting a number of the first clock signals in a first period set in advance a plurality of times;
a jitter detection unit that performs averaging processing of count values for the plurality of times by the first counting unit to detect jitter due to the fluctuation in the power supply voltage;
a light receiving element that emits a light signal to an object and receives a reflected light signal from the object every second period including a plurality of the first periods;
a light reception information detection unit that detects timing information at which the reflected light signal is received; and
a distance calculation unit that measures a distance to the object on a basis of the timing information detected by the light reception information detection unit.

2. The distance measuring device according to claim 1, wherein the light reception information detection unit generates a first histogram representing an appearance frequency for each of timings at which the reflected light signal is received.

3. The distance measuring device according to claim 1, wherein the first period is a fixed period.

4. The distance measuring device according to claim 1, wherein the jitter detection unit calculates a difference between a count value by the first counting unit acquired at a timing of a start of the first period and a count value by the first counting unit acquired at a timing of an end of the first period a plurality of times, and averages a plurality of the differences.

5. The distance measuring device according to claim 1, further comprising
a second counting unit that repeats operation of counting a number of the first clock signals in the second period a plurality of times, wherein
the jitter detection unit calculates an average value of count values by the second counting unit counted for each of the second periods and an average value of count values by the first counting unit counted for each of the individual first periods in the second period, and detects the jitter on a basis of a reciprocal of the average value of the count values by the second counting unit counted for each of the second periods and a reciprocal of the average value of the count values by the first counting unit counted for each of the individual first periods in the second period.

6. The distance measuring device according to claim 2, further comprising
a histogram correction unit that corrects the first histogram on a basis of the jitter detected by the jitter detection unit to generate a corrected histogram, wherein
the distance calculation unit measures the distance to the object on a basis of the corrected histogram.

7. The distance measuring device according to claim 6, wherein the histogram correction unit corrects the first histogram such that an appearance frequency for each of timings of an ambient light signal received by the light receiving element is constant to generate the corrected histogram.

8. The distance measuring device according to claim 6, further comprising:
a first time digital converter that generates a first digital signal according to the reflected light signal received by the light receiving element;
a pseudo input generation unit that generates a pseudo input signal according to an ambient light signal not including the reflected light signal;
a second time digital converter that converts the pseudo input signal into a second digital signal; and
a second histogram generation unit that generates a second histogram representing an appearance frequency for each of timings at which the ambient light signal is received, wherein
the light reception information detection unit generates the first histogram on a basis of the first digital signal, and
the histogram correction unit corrects the first histogram on a basis of the jitter detected by the jitter detection unit and the second histogram to generate the corrected histogram.

9. The distance measuring device according to claim 8, wherein the light reception information detection unit generates the first histogram corresponding to a signal including the reflected light signal and the ambient light signal, a signal including only the ambient light signal, or the reflected light signal not including the ambient light signal.

10. The distance measuring device according to claim 9, wherein the light reception information detection unit generates the first histogram in a pseudo manner on a basis of the signal including only the ambient light signal.

11. The distance measuring device according to claim 6, further comprising
a jitter correction unit that corrects a frequency characteristic of the jitter detected by the jitter detection unit, wherein
the histogram correction unit corrects the first histogram on a basis of the jitter corrected by the jitter correction unit to generate the corrected histogram.

12. The distance measuring device according to claim 11, wherein the jitter correction unit corrects at least one of an amplitude or a phase of the jitter detected by the jitter detection unit.

13. The distance measuring device according to claim 11, wherein the jitter correction unit corrects at least one of an amplitude or a phase of the jitter detected by the jitter detection unit, on a basis of temperature information and the jitter detected by the jitter detection unit.

14. The distance measuring device according to claim 2, further comprising a jitter addition unit that controls timings of at least some signals from when the light receiving element receives the reflected light signal to when the light reception information detection unit generates the first histogram on a basis of the jitter detected by the jitter detection unit.

15. The distance measuring device according to claim 14, further comprising:
a clock generation unit that generates a second clock signal having an oscillation frequency not depending on the fluctuation in the power supply voltage, on a basis of a reference clock signal;
a counting window generation unit that generates the first period in synchronization with the second clock signal; and
a light emission timing control unit that controls a light emission timing of a light emitting element that emits the light signal in synchronization with the second clock signal.

16. The distance measuring device according to claim 15, wherein
the jitter addition unit adds the jitter to the second clock signal, and
the light emission timing control unit controls the light emission timing of the light emitting element that emits the light signal in synchronization with the second clock signal to which the jitter is added.

17. The distance measuring device according to claim 16, wherein the jitter addition unit controls at least one of an oscillation frequency or a phase of the second clock signal on the basis of the jitter detected by the jitter detection unit.

18. The distance measuring device according to claim 14, further comprising:
a clock generation unit that generates a second clock signal having an oscillation frequency not depending on the fluctuation in the power supply voltage, on a basis of a reference clock signal;
a first time digital converter that generates a first digital signal according to the reflected light signal;
a first control unit that controls the first time digital converter and the light reception information detection unit;
a second control unit that controls the first control unit in synchronization with the second clock signal; and
a pixel array unit including a plurality of the light receiving elements, wherein
the jitter addition unit adds the jitter to at least one of a plurality of electric signals according to a plurality of the reflected light signals output from the plurality of the light receiving elements in the pixel array unit, a first control signal for controlling the first control unit, or a second control signal that is output from the second control unit and is for controlling the first control unit.

19. A distance measuring device comprising:
a light receiving element that emits a light signal to an object and receives a reflected light signal from the object every second period including a plurality of first periods;
a first time digital converter that generates a first digital signal according to the reflected light signal;
a first histogram generation unit that generates a first histogram representing an appearance frequency for each of timings at which the reflected light signal is received;
a pseudo input generation unit that generates a pseudo input signal according to an ambient light signal not including the reflected light signal;
a second time digital converter that converts the pseudo input signal into a second digital signal;
a second histogram generation unit that generates a second histogram representing an appearance frequency for each of timings at which the ambient light signal is received;
a histogram correction unit that corrects the first histogram on a basis of the second histogram to generate a corrected histogram; and
a distance calculation unit that measures a distance to the object on a basis of the corrected histogram.

20. The distance measuring device according to claim 8, further comprising
a pixel array unit including a plurality of the light receiving elements, wherein
a plurality of the pseudo input generation units and a plurality of the second time digital converters are provided in association with two or more of the light receiving elements arranged separately in the pixel array unit.
